(19) United States
(12) Patent Application Publication
(10) Pub. No.: US 2015/0221593 A1
(43) Pub. Date: Aug. 6, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Masaaki YAMAMOTO, Oita Oita (JP); Takeshi SUNADA, Oita Oita (JP); Mokuji KAGEYAMA, Oita Oita (JP); Kazuhiro TAKIMOTO, Oita Oita (JP)

(21) Appl. No.: 14/542,177

(22) Filed: Nov. 14, 2014

(30) Foreign Application Priority Data
Jan. 31, 2014 (JP) 2014-018051

(51) Int. Cl. H01L 23/522; H01L 21/768

(52) U.S. Cl. CPC H01L 23/5223; H01L 23/5226; H01L 21/76802; H01L 21/76879

(57) ABSTRACT

According to one embodiment, in a semiconductor device, a plurality of first wiring lines is provided in a first insulating film on a semiconductor substrate and is adjacent in a direction parallel to the semiconductor substrate. A second insulating film is provided on the first wiring lines and the first insulating film. A plurality of vias is provided in the second insulating film and is electrically connected to the first wiring lines. A third insulating film is provided on the vias and the second insulating film. Adjacent second wiring lines are provided in the third insulating film and are electrically connected to the vias. A fourth insulating film is provided on a sidewall of each of the adjacent second wiring lines, the sidewalls face each other. A conductive film abuts on the adjacent second wiring lines with the fourth insulating film interposed therebetween.

### CROSS REFERENCE TO RELATED APPLICATION

This application is based upon and claims the benefit of priority from the prior Japanese Patent Application No. 2014-018051, filed on Jan. 31, 2014, the entire contents of which are incorporated herein by reference.

### FIELD

Embodiments described herein relate generally to a semiconductor device and a method of manufacturing the semiconductor device.

### BACKGROUND

Devices such as a wireless power feeding device and a power amplifier are requested to be capable of passing a large current or withstanding a high voltage.

An UTM (Ultra-Thick Metal) structure having a thick wiring line to withstand the large current is employed in the devices.

A capacitance with large capacity is required for passing the large current.

### BRIEF DESCRIPTION OF THE DRAWINGS

FIG. 1 is a cross-sectional view showing a semiconductor device according to a first embodiment.

FIGS. 2 to 12 are cross-sectional views showing steps of manufacturing the semiconductor device in sequential order according to the first embodiment.

FIG. 13 is a cross-sectional view showing a semiconductor device according to a second embodiment.

### DETAILED DESCRIPTION

According to one embodiment, a semiconductor device includes a semiconductor substrate, a first insulating film, a plurality of first wiring lines, a second insulating film, a plurality of vias, a third insulating film, adjacent second wiring lines, a fourth insulating film, a conductive film. The first insulating film is provided on the semiconductor substrate. The plurality of first wiring lines are provided in the first insulating film and are adjacent in a direction parallel to the semiconductor substrate. The second insulating film is provided on the first wiring lines and the first insulating film. The plurality of vias are provided in the second insulating film, are adjacent in the direction parallel to the semiconductor substrate and are electrically connected to the first wiring lines. The third insulating film is provided on the vias and the second insulating film. The adjacent second wiring lines are provided in the third insulating film, are adjacent in the direction parallel to the semiconductor substrate and are electrically connected to the vias. The fourth insulating film is provided on a sidewall of each of the adjacent second wiring lines, the sidewalls face each other. The conductive film abuts on the adjacent second wiring lines with the fourth insulating film interposed between the conductive film and the adjacent second wiring lines.

Hereinafter, embodiments will be described with reference to the drawings. In the drawings, same reference characters denote the same or similar portions. The detailed description of the same reference characters is arbitrarily omitted, and only different reference characters are described.

### First Embodiment

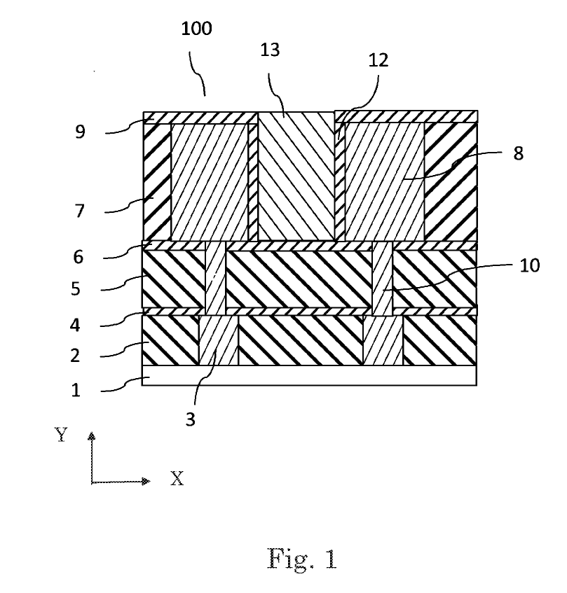

A semiconductor device in accordance with a first embodiment will be described with reference to FIG. 1. FIG. 1 is a cross-sectional view showing the semiconductor device of the first embodiment.

The semiconductor device 100 includes a semiconductor substrate 1, a first insulating film 2, first wiring lines 3, a first diffusion prevention film 4, a second insulating film 5, a second diffusion prevention film 6, a third insulating film 7, adjacent second wiring lines 8, a third diffusion prevention film 9, vias 10, a fourth insulating film 12, and a conductive film 13.

An UTM (Ultra-Thick Metal) structure is shown as one example of the semiconductor device of the embodiment.

The UTM has a wiring line thicker than a conventional wiring line in an insulating film. A thickness of the wiring line is 3000 nm, for example. In the embodiment, a MIM (Metal Insulator Metal) capacitor is formed using a sidewall of the thick wiring line. In the MIM capacitor employing the UTM structure of the embodiment, the conductive film 13 adjacent to the sidewall of the wiring line formed in the insulating film serves as a capacitor.

Firstly, the semiconductor device of the embodiment will be described.

In the UTM structure, multiple insulating films and wiring lines are laminated in a direction perpendicular to the semiconductor substrate 1. However the insulating films and wiring lines which are necessity minimum for an explanation of the structure of the embodiment are shown, others are not shown for omitting an explanation.

The semiconductor substrate 1 is made of silicon (Si), for example. The semiconductor substrate 1 is provided with an element region.

The first insulating film 2 is provided on the semiconductor substrate 1. The first insulating film 2 is a thermally-oxidized film, for example.

The first wiring lines 3 are provided in the first insulating film 2. The first wiring lines 3 are two or more wiring lines adjacent in a direction (X direction of Figure) parallel to the semiconductor substrate 1, the first insulating film 2 being interposed therebetween. The first wiring lines 3 are composed of a conductive material such as copper (Cu) provided in the first insulating film 2 through a barrier metal film, for example. The first wiring lines 3 are connected to elements which are formed on the element region of the semiconductor substrate 1. The first wiring lines 3 serve as wiring lines that draw electrodes of each of the elements outside or are electrically connected with the electrodes of each of the elements.

The first diffusion prevention film 4 is provided on the first wiring lines 3 and the first insulating film 2. The first diffusion prevention film 4 is provided in order to prevent copper atoms of the wiring line from diffusing into the insulating film. The first diffusion prevention film 4 serves as a stopper to stop an etching when etching the insulating film. A thickness of the first diffusion prevention film 4 is approximately 100 nm, for example.

The second insulating film 5 is provided on the first diffusion prevention film 4. A thickness of the second insulating film 5 is approximately 700 nm, for example.

The second diffusion prevention film 6 is provided on the second insulating film 5. A thickness of the second diffusion prevention film 6 is approximately 200 nm, for example.

The third insulating film 7 is provided on the second diffusion prevention film 6. A thickness of the third insulating film 7 is approximately 3400 nm, for example.

The second wiring lines 8 are provided in the third insulating film 7. The second wiring lines 8 are two or more wiring lines adjacent in the direction parallel to the semiconductor substrate 1, the third insulating film 7 being interposed therebetween. The second wiring lines 8 are made of copper (Cu), for example.

The third diffusion prevention film 9 is provided on the third insulating film 7 and the second wiring lines 8. The third diffusion prevention film 9 is made of silicon nitride (SiN), for example. A thickness of the third diffusion prevention film 9 is approximately 100 nm, for example.

The vias 10 are provided in the second insulating layer 5. The vias 10 are provided in a direction (Y direction of Figure) perpendicular to the semiconductor substrate 1 in order to electrically connect the first wiring lines 3 and the second wiring lines 8. One end of each of the vias 10 is electrically connected to the first wiring line 3. The other end of each of the vias 10 is electrically connected to the second wiring 8.

The second wiring lines 8 are provided in the third insulating film 7, extending from the surface of the third insulating film 7 toward the semiconductor substrate 1, in the range of the whole thickness of the third insulating film 7.

The fourth insulating film (capacitance insulating film) 12 is provided on a sidewall of each of the adjacent second wiring lines 8, the sidewalls facing each other. The fourth insulating film 12 is made of silicon nitride (SiN), for example. The silicon nitride (SiN) serves as dielectric.

The conductive film 13 is provided between the adjacent second wiring lines 8, the fourth insulating film 12 being interposed between the adjacent second wiring lines 8 and the conductive film 13. That is to say, the conductive film 13 abut on one of the adjacent second wiring lines 8 with the fourth insulating film 12 interposed between the adjacent second wiring lines 8 and the conductive film 13, and abut on the other of the adjacent second wiring lines 8 with the fourth insulating film 12 interposed between the adjacent second wiring lines 8 and the conductive film 13. The conductive film 13 is made of titan nitride (TiN), for example. The conductive film 13 is provided in the range of the whole thickness of the second wiring lines 8 in a direction perpendicular to the semiconductor substrate 1. That is the conductive film 13 covers whole of the sidewall of each of the adjacent second wiring lines 8 through the fourth insulating film 12.

In the structure described above, the second wiring line 8 and the conductive film 13 each serve as an opposite electrode of a capacitor. The fourth insulating film 12 serves as a dielectric of the capacitor. That is to say, since the fourth insulating film 12 is interposed between the second wiring line 8 and the conductive film 13, the capacitor is formed. In the UTM structure, since the second wiring lines 8 are thick in the direction (Y direction) perpendicular to the semiconductor substrate 1, the sidewall of the second wiring line 8 enables an area of the electrode of the capacitor to enlarge sufficiently. The sidewall of the second wiring line 8 enables the capacitor to have a large capacity. Since the conductive film 13 is a common electrode, capacitors each formed on the sidewall of each of the adjacent second wiring lines 8 are electrically connected in parallel. Two or more capacitors each formed on the sidewall of each of the adjacent second wiring lines 8 enable it to form a capacitor with large capacity on the semiconductor substrate 1 as a whole. A thickness of the wiring line of the UTM structure is equal to or above 3.5 μm.

A method of manufacturing the semiconductor device in accordance with the embodiment will be described with reference to drawings.

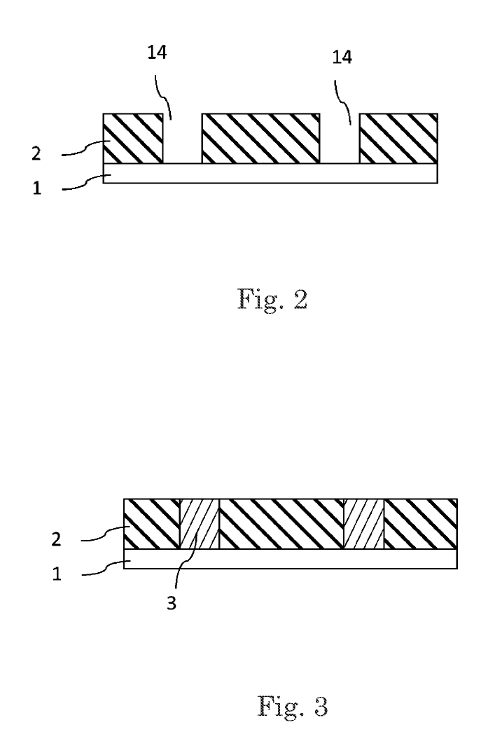

As shown in FIG. 2, trenches 14 to form the first wiring lines 3 are formed in the second insulating film 2. The trenches 14 are formed passing through the first insulating film 2 from the upper surface of the first insulating film 2 so as to reach the semiconductor substrate 1 using photo lithography technique and dry-etching technique.

The barrier metal film (not shown) is formed on a sidewall and bottom of the trench 14. The barrier metal film is provided to prevent copper (Cu) atoms of the wiring line from diffusing into the insulating film. The barrier metal film is made of tantalum (Ta), tantalum nitride (TaN), titanium (Ti), titanium nitride (TiN) and the like, and is formed by sputtering method, for example.

The first wiring lines 3 are formed so as to fill the trenches 14 with the barrier metal film interposed between the first lines 3 and the first insulating film 2. As shown in FIG. 3, a copper (Cu) film is formed so as to fill the trenches 14 of the first insulating film 2 by sputtering method, plating and the like, and is planarized by CMP (Chemical Mechanical Polishing) method, so that the first wiring lines 3 are formed. The multiple first wiring lines 3 are disposed in the first insulating film 2.

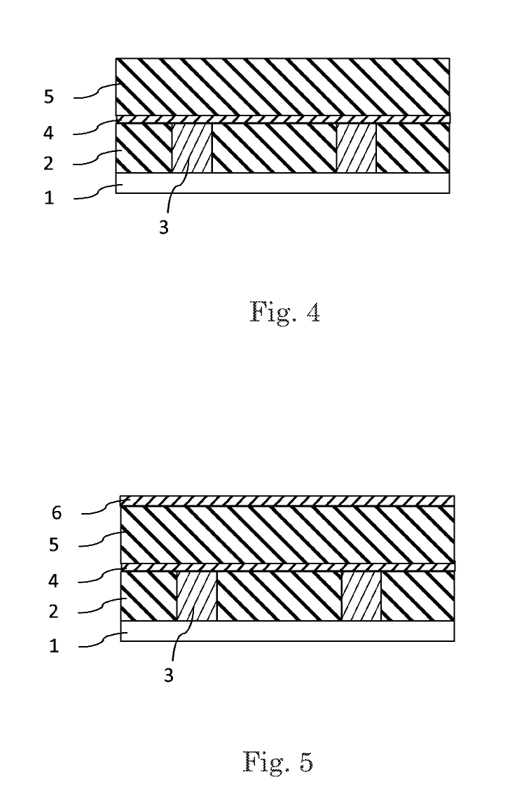

As shown in FIG. 4, the first diffusion prevention film 4 is formed on the first insulating film 2 and the first wiring lines 3. The first diffusion prevention film 4 is made of silicon nitride (SiN), for example, by plasma-CVD method and the like. The first diffusion prevention film 4 is provided in order to prevent copper (Cu) atoms of the first wiring lines 3 from diffusing into the second insulating film 5 which is to be formed thereon. A thickness of the first diffusion prevention film 4 is approximately 100 nm, for example.

The second insulating film 5 is formed on the first diffusion prevention film 4. The second insulating film 5 is made of silicon oxide (SiO₂) formed by plasma-CVD method, for example using TEOS (Tetraethoxysilane), for example as a material. A thickness of the second insulating film 5 in the direction (Y direction) perpendicular to the semiconductor substrate 1 is approximately 700 nm, for example.

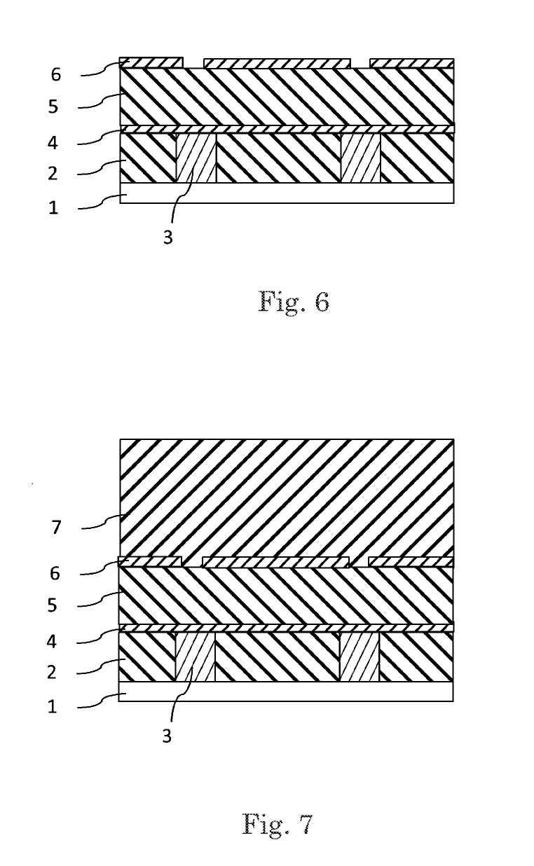

As shown in FIG. 5, the second diffusion prevention film 6 is formed on the second insulating film 5. the second diffusion prevention film 6 is made of SiN, for example. The SiN is formed by plasma-CVD method and the like. A thickness of the second diffusion prevention film 6 in the direction (Y direction) perpendicular to the semiconductor substrate 1 is approximately 200 nm, for example.

A resist pattern (not shown) is formed on the second diffusion prevention film 6 in order to form openings of the second diffusion prevention film 6. The openings are used to form trenches 16 in which the vias 10 are provided. As shown in FIG. 6, a portion not covered with the resist pattern of the second diffusion prevention film 6 is removed by RIE (Reactive Ion Etching) to form an opening reaching the second insulating film 5 in the second diffusion prevention film 6.

As shown in FIG. 7, the third insulating film 7 is formed on the second diffusion prevention film 6. The third insulating film 7 is made of silicon oxide (SiO₂) formed by plasma-CVD method, for example using TEOS (Tetraethoxysilane) or silane (SiH₄), for example as a material. A thickness of the third insulating film 7 in the direction (Y direction) perpendicular to the semiconductor substrate 1 is approximately 3400 nm, for example.

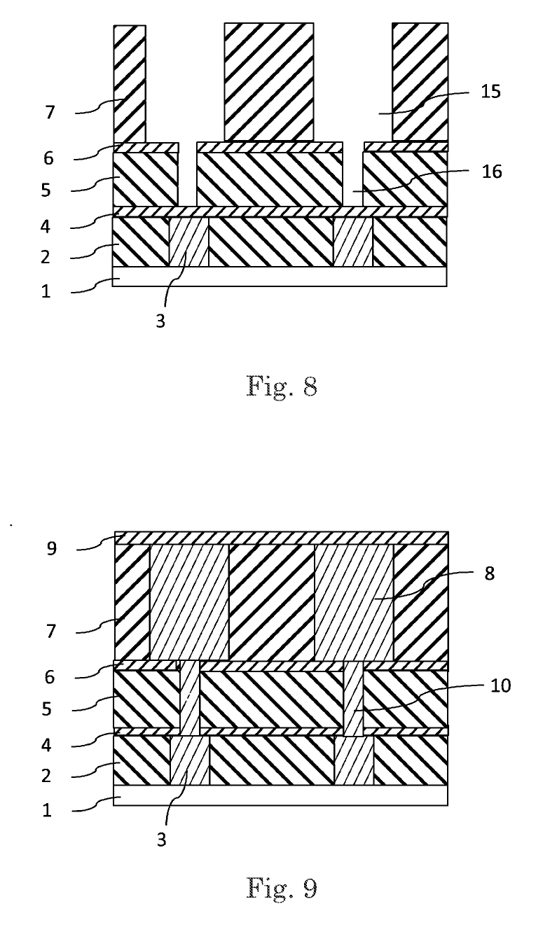

As shown in FIG. 8, the third insulating film 7 is etched by RIE method using a resist film (not shown) as a mask to form trenches 15. The trenches 15 passing through the third insulating film 7 extend to the second diffusion prevention film 6 from the upper surface of the third insulating film 7 so as to reach the openings of the second diffusion prevention film 6. That is to say, the second diffusion prevention film 6 and the opening of the second diffusion prevention film 6 are exposed at a bottom of the trench 15. A portion of the second insulating film 5 exposed in the opening of the second diffusion prevention film 6 is selectively etched by RIE to form the trench 16 in which the via 10 is provided. The trench 16 formed in the second insulating film 5 extends to the first insulating film 4 from the opening of the second diffusion prevention film 6.

A barrier metal film (not shown) is formed on a sidewall and bottom of each of the trenches 15, 16 formed by etching. The barrier metal film is provided in order to prevent copper (Cu) atoms of the wiring line from diffusing into the insulating film. The barrier metal film is formed by sputtering method, for example using a tantalum (Ta) or tantalum nitride (TaN) target.

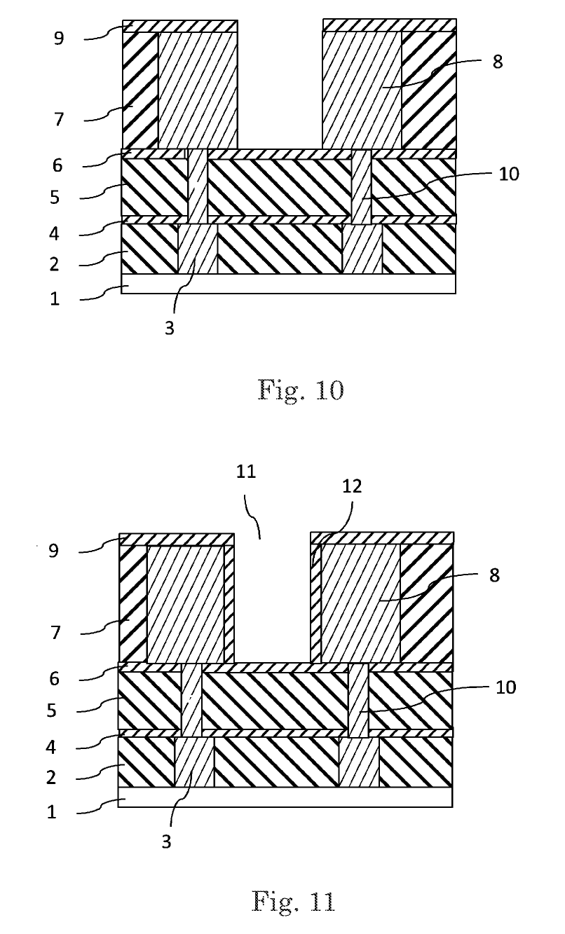

As shown in FIG. 9, the second wiring lines 8 and the vias 10 each are formed by what is called dual damascene process. In the dual damascene process, the trenches 15, 16 each are filled with a copper (Cu) film, for example through the barrier metal film by sputtering method, plating method and the like, and then the surface is planarized.

An annealing treatment is performed in order to increase an adhesion between the barrier metal film and the wiring line which is employed for the first wiring lines 3, the second wiring lines 8 and vias 10.

The copper film and barrier metal film on the third insulating film 7 and second wiring lines 8 are removed by CMP method.

The third diffusion prevention film 9 is formed on the second wiring lines 8 and the third insulating film 7. The third diffusion prevention film 9 is made of silicon nitride (SiN), for example. A thickness of the third diffusion prevention film 9 is approximately 100 nm, for example.

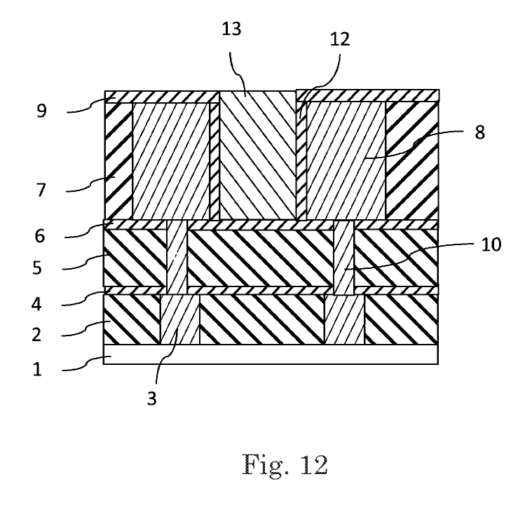

As shown in FIG. 10, a portion of the third insulating film 7 between the adjacent second wiring lines 8 is removed in order to form a capacitor between the adjacent second wiring lines 8. Photo lithography technique, etching technique and the like are employed in order to remove the portion of the third insulating film 7 between the adjacent second wiring lines 8.

As shown in FIG. 11, a silicon nitride (SiN) film, for example is formed on a sidewall of each of the adjacent second wiring lines 8 exposed after removing the third insulating film 7 by sputtering method, for example. The sidewalls face each other. Therefore, the fourth insulating film 12 is formed on each of the facing sidewalls.

As shown in FIG. 12, the conductive film 13 such as a titanium nitride film is formed between the adjacent second wiring lines 8 with the silicon nitride film interposed between the adjacent second wiring lines 8 and the conductive film 13 by sputtering method, for example. An extra portion of the titanium nitride film on the silicon nitride film is removed by CMP. Therefore, the conductive film 13 between the adjacent second wiring lines 8 abut on the sidewall of each of the second wiring lines 8 through the fourth insulating film 12.

As described above, in the method of manufacturing the semiconductor device of the embodiment, the second wiring lines 8 serve as one electrode of the capacitor. Therefore, forming the fourth insulating film 12 which is a dielectric of the capacitor, and the conductive film 13 which is the other electrode of the capacitor, the capacitor can be formed on the semiconductor substrate 1. That is to say, in the method of manufacturing the semiconductor device of the embodiment, a step of forming one electrode of the capacitor can be omitted. An advantage that manufacturing process may be simplified is obtained.

### Second Embodiment

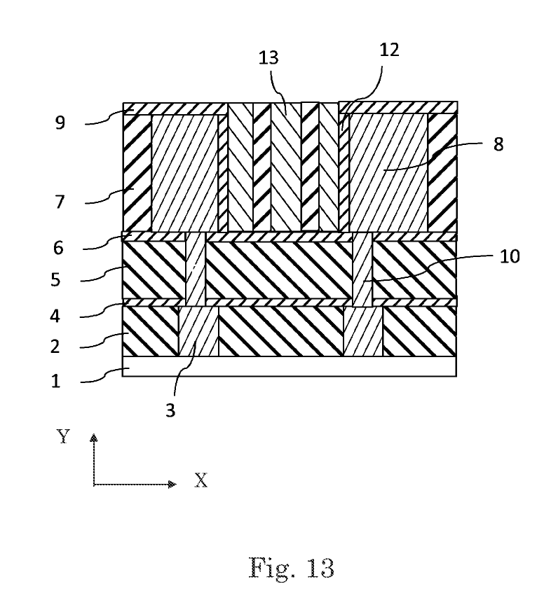

A semiconductor device in accordance with a second embodiment will be described with reference to FIG. 13. FIG. 13 is a cross-sectional view showing the semiconductor device of the embodiment.

The semiconductor device of the embodiment is different from the semiconductor device of the first embodiment in that at least two or more conductive films 13 are provided between the adjacent second wiring lines 8 in the third insulating film 7. The multiple conductive films 13 are interposed between the adjacent second wiring lines 8 through the fourth insulating film 12 in the direction (X direction) parallel to the semiconductor substrate 1. The multiple conductive films 13 each are separated each other by the third insulating film 7. More specifically, the multiple conductive films 13 each abut on the sidewalls of the adjacent second wiring lines 8 through the fourth insulating film 12. The third insulating films 7 separating the multiple conductive films 13 and the fourth insulating film 12 serve as the dielectric of the capacitor.

The conductive films 13 serve as the electrode of the capacitor. That is, since the conductive films 13 separated by the third insulating film 7 are formed between the adjacent second wiring lines 8, a structure is realized, in which a portion as the electrode of the capacitor and a portion as the dielectric of the capacitor are alternately formed between the adjacent second wiring lines 8.

The above structure enables it to form a lot of capacitors on the semiconductor substrate 1. A distance between the electrodes of the capacitor becomes short when the number of capacitors provided between the second wiring lines 8 is increased. The short distance between the electrodes enables it to form a capacitor with high capacity.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate;
a first insulating film provided on the semiconductor substrate;
a plurality of first wiring lines provided in the first insulating film and being adjacent in a direction parallel to the semiconductor substrate;
a second insulating film provided on the first wiring lines and the first insulating film;
a plurality of vias provided in the second insulating film, being adjacent in the direction parallel to the semiconductor substrate and being electrically connected to the first wiring lines;
a third insulating film provided on the vias and the second insulating film;
adjacent second wiring lines provided in the third insulating film, being adjacent in the direction parallel to the semiconductor substrate and being electrically connected to the vias;
a fourth insulating film provided on a sidewall of each of the adjacent second wiring lines, the sidewalls facing each other; and
a conductive film abutting on the adjacent second wiring lines with the fourth insulating film interposed between the conductive film and the second wiring lines.

2. The semiconductor device according to claim 1, wherein the second wiring lines are provided in the same insulating film.

3. The semiconductor device according to claim 1, wherein the conductive film is provided in the range of the whole thickness of the second wiring line in a direction perpendicular to the semiconductor substrate.

4. The semiconductor device according to claim 2, wherein the conductive film is provided in the range of the whole thickness of the second wiring line in a direction perpendicular to the semiconductor substrate.

5. The semiconductor device according to claim 1, wherein a first diffusion prevention film is provided between the first insulating film and the second insulating film and between the first wiring lines and the second insulating film.

6. The semiconductor device according to claim 1, wherein a second diffusion prevention film is provided between the second insulating film and the third insulating film and between the second insulating film and the second wiring lines.

7. The semiconductor device according to claim 1, wherein a third diffusion prevention film is provided on the third insulating film and the second wiring lines.

8. The semiconductor device according to claim 1, wherein the conductive film is composed of at least two or more conductive films in an adjacent direction of the adjacent second wiring lines.

9. The semiconductor device according to claim 8, wherein the third insulating film is provided between the two or more conductive films.

10. The semiconductor device according to claim 1, wherein the third insulating film is thicker than the second insulating film.

11. The semiconductor device according to claim 1, wherein the first wiring lines are provided in the first insulating film with a barrier metal film interposed between the first wiring lines and the first insulating film.

12. A method of manufacturing a semiconductor device, comprising:
forming a first insulating film on a semiconductor substrate;
forming a plurality of first wiring lines in the first insulating film, the first wiring lines being adjacent in a direction parallel to the semiconductor substrate;
forming a second insulating film on the first wiring lines and the first insulating film;
forming a plurality of vias in the second insulating film, the vias being adjacent in the direction parallel to the semiconductor substrate and being electrically connected to the first wiring lines;
forming a third insulating film on the vias and the second insulating film;
forming a plurality of second wiring lines in the third insulating film, the second wiring lines being adjacent in the direction parallel to the semiconductor substrate and being electrically connected to the vias;
removing a portion of the third insulating film between the adjacent second wiring lines to expose a sidewall of each of the adjacent second wiring lines, the sidewalls facing each other;
forming a fourth insulating film on the exposed sidewall of each of the second wiring lines, the exposed sidewalls facing each other; and
forming a conductive film so as to abut on the sidewall of each of the second wiring lines with the fourth insulating film interposed between the conductive film and the second wiring lines, the sidewalls facing each other.

13. The method of manufacturing the semiconductor device according to claim 12, wherein
the conductive film is formed between the third insulating film and the sidewall of each of the adjacent second wiring lines, the sidewalls facing each other.

14. The method of manufacturing the semiconductor device according to claim 12, wherein
a first diffusion prevention film is formed on the first insulating film and the first wiring lines.

15. The method of manufacturing the semiconductor device according to claim 12, wherein
a second diffusion prevention film is formed on the second insulating film.

16. The method of manufacturing the semiconductor device according to claim 12, wherein
a third diffusion prevention film is formed on the third insulating film and the second wiring lines.

17. The method of manufacturing a semiconductor device according to claim 12, wherein
a barrier metal film is formed between the first wiring lines and the first insulating film and between the first wiring lines and the semiconductor substrate.
